(19) United States
(12) Patent Application Publication
(10) Pub. No.: US 2008/0073060 A1
(43) Pub. Date: Mar. 27, 2008

(54) Heat sink

(75) Inventor: Tzu-Chou Chia, Hsin-Chuang (TW)

Correspondence Address: Asia Vital Components Co., Ltd., P.O. BOX 1-195, YUNG HO, TAIPEI HSIEN, 235, omitted

(73) Assignee: ASIA VITAL COMPONENTS CO., LTD., HSIN-CHUANG (TW)

(21) Appl. No.: 11/527,094

(22) Filed: Sep. 27, 2006

(51) Int. Cl. H05K 7/20

(52) U.S. Cl. 165/80.2; 361/697

(57) ABSTRACT

A heat sink is disclosed. The heat sink comprises a ring, an air inlet, a securing portion and a fan. The ring comprises an air inlet side and an air outlet side, wherein the air outlet side corresponds to at least one heating element. The air inlet vertically protrudes outwards along the ring in a horizontal direction forming an arched side having at least one arch structure, wherein the arched side protrudes out of the ring. The securing portion comprises a supporting chassis positioned on said air inlet side and a plurality of blades radially positioned connecting the supporting chassis and the ring. The fan comprises a hub and a plurality of blades positioned around the hub and is positioned inverted on said supporting chassis, wherein a side of the fan facing opposite to the securing portion correspond to the heating element.

### BACKGROUND OF THE INVENTION

1. Field of the invention

The present invention generally relates to a heat sink, and more particularly to a heat sink having fan positioned inverted on an air inlet.

2. Description of the Related Art

The conventional heat sink, as shown in FIG. 1, comprises a ring 10 having an air inlet side 101 and an air outlet side 102 respectively disposed on the two sides thereof. A supporting chassis 11 is positioned on the air outlet side 102 and a plurality of ribs 103 are disposed connecting the ring 10 and the supporting chassis 11 to secure the supporting chassis 11. A fan 14 is axially and rotatably positioned on the supporting chassis 11. Thus, a portion of the fan 14 not connected to the supporting chassis 11 is positioned facing the air inlet side 101. The ring 10 and the air inlet side 101 are vertically positioned. When the fan 14 rotates, the air flows through the air inlet side 101 and then the fan 14 blows the air out via the air outlet side 102.

However, above conventional heat sink has the following defects. Because the ring 10 in the air inlet side 101 is vertically positioned, and therefore when the air flows into the air inlet 101, the eddy generated thereby disturbs the airflow and adversely affect the volume of the airflow. Thus, this phenomenon increases the noise. Furthermore, the air flowing out of the air outlet side 102 is blocked by the rib 103, the impact of the airflow on the rib 103 generates disturbance, which may further increase the noise, and correspondingly, the surface area of air coming in direct contact with the heating element is decreased (not shown). Thus, the heat dissipation is accordingly decreased.

### SUMMARY OF THE INVENTION

Accordingly, the present invention is directed to a heat sink having an air inlet at the air inlet side such that an arched side of the air inlet is adopted to smoothly guide air through the air inlet side and thereby increase the efficiency of heat dissipation and as well as reduce the noise.

According to an aspect of the present invention, the air inlet side comprises a plurality of blades connected to a ring with a supporting chassis for increasing the volume and pressure of the airflow, and also avoids any objects from entering therein.

According to another aspect of the present invention, the air outlet side comprises no barricade to disturb or resist the airflow. Thus, the noise may be reduced and surface area of the heating element surface area coming in direct contact with air is substantially increased, and thus the heat dissipation effect may be effectively increased.

According to another aspect of the present invention, the air inlet protrudes out of the ring, wherein the protruding portion extends up to a vertical distance such that the dimension of the air inlet is larger than that of the air outlet side to increase the airflow area.

In accordance with the above purposes, the present invention provides a heat sink comprising a ring, an air inlet, a securing portion and a fan. The ring comprises an air inlet side and an air outlet side on the two sides thereof, respectively. The air inlet is positioned along the air inlet side of the ring. The air inlet comprises an arched side having at least one arch that extends outwardly along axial direction and the horizontal direction of the ring. The securing portion comprises a supporting chassis and a plurality of blades. The blades position the supporting chassis in the air tunnel of the ring close to the air inlet side. The fan may be positioned axially inverted on the supporting chassis of the securing portion. Thus, the side of the fan facing opposite to the securing portion corresponds to a heating element positioned at the air outlet side. The blades of the air inlet smoothly guide the air through the air inlet side. The blades are also adopted for increasing the volume and pressure of the airflow. Furthermore, there is no barricade blocking the air from flowing to the air outlet side. Thus, the heat dissipation can be promoted and the noise can be reduced.

### BRIEF DESCRIPTION OF THE DRAWING

For a more complete understanding of the present invention, reference will now be made to the following detailed description of preferred embodiments taken in conjunction with the following accompanying drawings.

FIG. 1 is a sectional view of a conventional heat sink.

FIG. 2 is a sectional view of a heat sink according to an embodiment of the present invention.

FIG. 3 is a sectional view of a heat sink according to an embodiment of the present invention.

FIG. 4 is a side view of a heat sink according to an embodiment of the present invention.

FIG. 5 is view of a heat sink having hole in the ring according to an embodiment of the present invention.

FIG. 6 is view of a heat sink having hole in the ring according to another embodiment of the present invention.

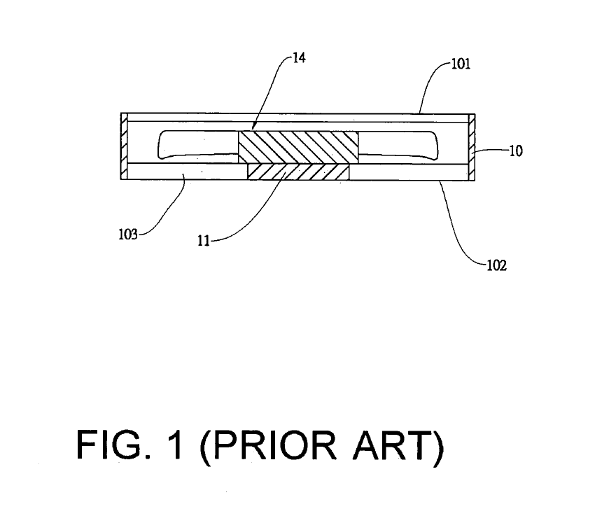

### DETAIL DESCRIPTION OF THE INVENTION

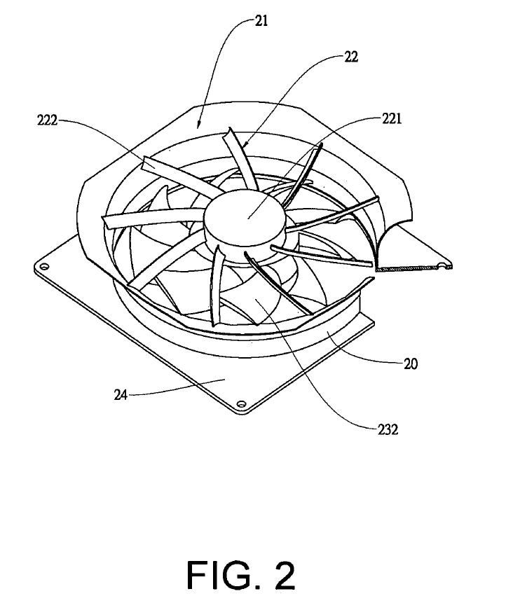

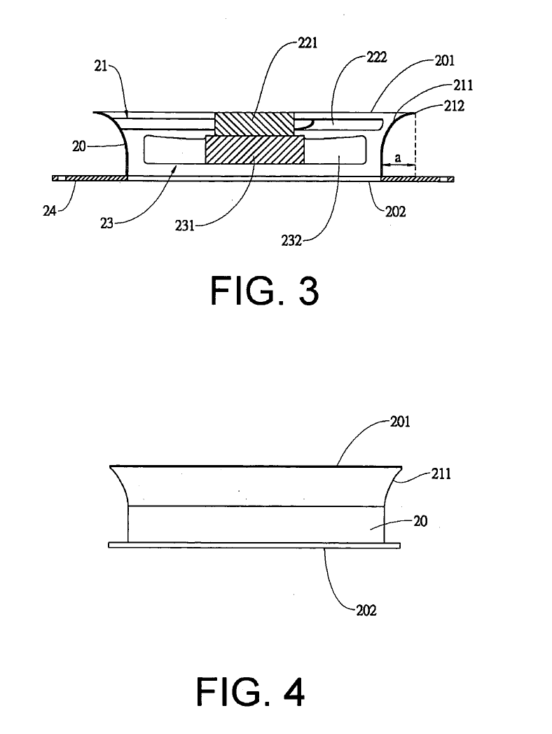

Referring to FIGS. 2 and 3, the structure of a heat sink according to an embodiment of the present invention comprises a ring 20, an air inlet 21, a securing portion 22 and a fan 23. The ring 20 is vertically positioned and comprises an air inlet side 201 and an air outlet side 202. The air inlet 21 vertically protrudes outwards along the ring 20 in a horizontal direction forming an arched side 211 with at least one arch structure. The arched side 211 may comprise a smooth shape, a trumpet shape or a stair-case shape. The ring 20 comprises a protruding portion 212 vertically protruding there-from. The dimension of the air inlet 21 is slightly larger than that of the air outlet side 202. Thus, the airflow area is significantly increased.

The securing portion 22 comprises a support chassis 221 and a plurality of blades 222. The support chassis 221 is positioned on the air inlet side 201 of the ring 20, and the blades 222 are radially positioned connecting the supporting chassis 221 and the ring 20 to secure the support chassis 221. The fan 23 comprises a hub 231 and blades 232 positioned around the hub 231. The fan 23 is axially positioned inverted on the chassis 221 such that the side of the fan 23 facing opposite to supporting chassis 221 corresponds to the air outlet side 202.

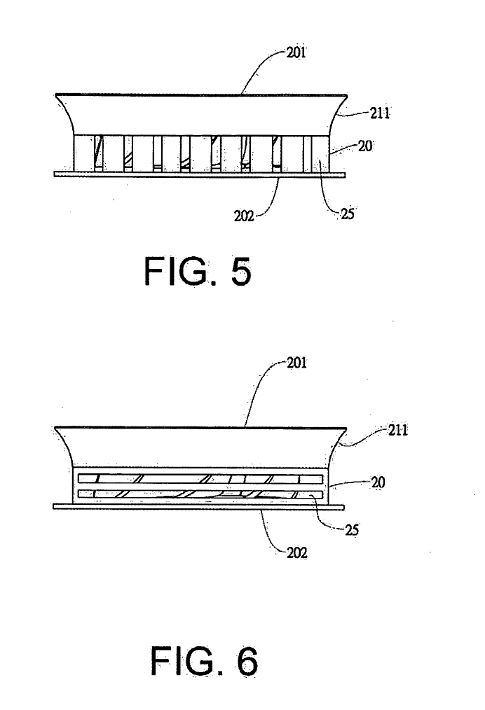

The above air outlet side 202 of the ring 20 is positioned corresponding to the heating element (not shown), for example, a radiator, a CPU or the alike. The air outlet side 202 has a least one securing portion 24 positioned on the flange for assembling onto the heating element. The securing portion 24, according to an embodiment of the present invention, comprises four portions correspondingly positioned on the ring 20. Referring to FIG. 4, the ring 20 may be comprised of a continuous circular shape. The ring 20 comprises a plurality of holes 25 as shown in FIGS. 5 and 6 to increase airflow into the ring 20 and thereby increase the volume of airflow. The shape of the holes 25 may be various, for example, vertical holes or horizontal holes.

Referring FIG. 3, when the fan 23 rotates, air enters into the air inlet 21 from the air inlet side 201 and passes by the blades 222. Thereafter, the air flows and comes in contact with the heating element. Because the air inlet 21 comprises the larger dimension than that of the air outlet side 202, the volume of airflow can be increased. The air inlet 21 guides the air to the air inlet side 201 along the arched side 211 so that the eddy and noise can be reduced. Thus, the blades 222 increase the volume and pressure of the airflow. When the air enters the fan 23, the rotation of the blades 232 increase the airflow and guides the air towards the heating element via air outlet side 202. Because the air outlet side 202 has no barricade blocking or resisting the airflow, and therefore the air flowing out of the air outlet side 202 is not disturbed. Thus, the noise can be reduced and the volume of air coming in contact with the heating element can be increased.

The above blades 222 can keep away any unexpected object from entering into the ring 20 when the fan 23 rotates. Although the figures above show a different configuration of the curve of the blades 222 compared to the blades 232, the configuration of the curve of the blades 222 can be also be same as that of the blades 232 (not shown).

While the invention has been described in conjunction with a specific best mode, it is to be understood that many alternatives, modifications, and variations will be apparent to those skilled in the art in light of the foregoing description. Accordingly, it is intended to embrace all such alternatives, modifications, and variations in which fall within the spirit and scope of the included claims. All matters set forth herein or shown in the accompanying drawings are to be interpreted in an illustrative and non-limiting sense.

What is claimed is:

1. A heat sink, comprising
a ring, comprising an air inlet side and an air outlet side, wherein said air outlet side corresponds to at least one heating element;
an air inlet, vertically protruding outwards along said ring in a horizontal direction forming an arched side having at least one arch structure, wherein said arched side protrudes out of said ring;
a securing portion, comprising a supporting chassis positioned on said air inlet side and a plurality blades radially positioned connecting said supporting chassis and said ring;
a fan, comprising a hub and a plurality of blades positioned around said hub, positioned inverted on said supporting chassis, wherein a side of said fan facing opposite to said securing portion correspond to said heating element, wherein air passes said blades of said air inlet side and flows towards said fan and said fan blows the air towards said heating element.

2. The heat sink accordingly to claim 1, wherein said ring comprises a continuous circular shape.

3. The heat sink accordingly to claim 1, wherein said ring has a plurality of holes.

4. The heat sink accordingly to claim 3, wherein said holes comprise vertical shaped holes.

5. The heat sink accordingly to claim 3, wherein said holes comprise linear shaped holes.

6. The heat sink accordingly to claim 1, wherein said air outlet side has at least one securing portion formed at a flange thereof.

7. The heat sink accordingly to claim 1, wherein said blades are curved along a same direction as that of said blades.

8. The heat sink accordingly to claim i, wherein said arched side comprises a smooth line shape, a trumpet shape or a stair-case shape.

9. The heat sink accordingly to claim 1, wherein said arched side protrudes a vertical distance from said vertical ring.
